(19) United States
(12) Patent Application Publication
(10) Pub. No.: US 2002/0110169 A1
(43) Pub. Date: Aug. 15, 2002

(54) Vertical cavity surface emitting laser device and vertical cavity surface emitting laser array

(76) Inventors: Norihiro Iwai, Tokyo (JP); Toshikazu Mukaihara, Tokyo (JP); Noriyuki Yokouchi, Kanagawa (JP); Akihiko Kasukawa, Tokyo (JP)

Correspondence Address: KNOBBE MARTENS OLSON & BEAR LLP, 620 NEWPORT CENTER DRIVE, SIXTEENTH FLOOR, NEWPORT BEACH, CA, 92660, US

(21) Appl. No.: 09/782,723

(22) Filed: Feb. 13, 2001

(51) Int. Cl. H01S 5/00

(52) U.S. Cl. 372/43; 372/50

(57) ABSTRACT

A vertical cavity surface emitting laser device and a vertical cavity surface emitting laser array are provided for suppressing heat generation in and an increased operating voltage of the device. The vertical cavity surface emitting laser device is formed with a bottom DBR mirror layer structure and a top DBR mirror layer structure on a semiconductor substrate. An active layer and a current confinement layer are interposed between the two mirror layer structures. A portion, including the top DBR mirror layer structure and an underlying region extending at least to a lower end surface of the current confinement layer, is formed in a columnar mesa structure. An upper end surface of the mesa structure has an area larger than a cross section of the mesa structure near the current confinement layer.

### BACKGROUND OF THE INVENTION

1. Field of the Invention

The present invention relates to a vertical cavity surface emitting laser device and a vertical cavity surface emitting laser array suitable for use as light sources for optical communications and so on.

2. Prior Art

A vertical cavity surface emitting laser (VCSEL) device which emits laser light in a direction perpendicular to a substrate has been recently noted as a light source for optical-fiber based data communications (optical interconnection) and optical computers because a circular shape of a beam emitted therefrom facilitates a connection with an optical fiber, and a short length of a resonator therein permits oscillation of single mode light. Also, since the vertical cavity surface emitting laser device has an active layer of a small region, a threshold current can be set lower (below several mA). Further, a multiplicity of the devices arranged in an array form is expected to be applied as a high density optical integrated device.

An example of the vertical cavity surface emitting laser device as described above is illustrated in FIG. 1. The illustrated laser device comprises, on an n-type GaAs substrate 100 (approximately 150 μm in thickness), a bottom DBR (distributed Bragg reflector) mirror layer structure 110 comprised of 25 pairs of n-type Al_{0.2}Ga_{0.8} As layers/n-type Al_{0.9}Ga_{0.1}As layers; a GaAs active layer 120 forming a quantum well structure; a current confinement layer 140; and a top DBR mirror layer structure 150 comprised of 23 pairs of p-type Al_{0.2}Ga_{0.8}As layers/p-type Al_{0.9}Ga_{0.1}As layers, which are laminated in this order.

A portion including the top DBR mirror layer structure 150 and an underlying region extending to a lower end surface of the current confinement layer 140 (interface between the current confinement layer 140 and the active layer 120) forms a cylindrical mesa structure (having a diameter of 30 μm) 200. On an upper end surface 200a of the mesa structure 200, a ring-shaped p-type electrode 160 (having a width of 5 μm and an outer diameter of approximately 30 μm) is formed concentrically with the mesa structure 200. On a back surface of the substrate 100, an n-type electrode 180 is disposed.

For manufacturing this laser device, the respective layers mentioned above are first laminated on the substrate 100, and then the resulting layered structure is dry etched, for example, by reactive ion beam etching (RIBE) perpendicularly downward from the top surface of the structure to form the mesa structure 200 in a cylindrical shape. At this time, however, the current confinement layer 140 has not yet been formed.

Subsequently, the mesa structure formed by dry etching is thermally treated in a high temperature steam atmosphere (for example, a heat treatment at a temperature of 400° C. for 10 minutes). In this event, when p-type Al_{0.98}Ga_{0.02}As, for example, is used as a semiconductor material for forming the current confinement layer 140, this layer is oxidized from a side edge toward the core, with the result that an outer portion becomes an insulating layer 140a mainly comprised of an Al oxide, and a core portion remains as an electrically conductive layer 140b comprised of unoxidized AlGaAs. In this way, the current confinement layer 140 is formed in the mesa structure 200.

The foregoing surface emitting laser device is constructed to emit laser light (in an 850 nm band) from a central surface (light emitting surface) in the upper end surface 200a of the mesa structure, on which a p-type electrode is not formed. In addition, since the laser device has a short length of a resonator comprised of the respective reflecting mirror structures 110, 150, single mode light is readily oscillated. Further, since a current is intensively injected into the conductive layer 140b in the current confinement layer 140, a threshold current is advantageously reduced. The surface of the device is passivated with an SiNx film (silicon nitride film) 190.

The foregoing surface emitting laser device is constructed such that the laser light resonates in a direction perpendicular to the substrate between the top DBR mirror layer structure and the bottom DBR mirror layer structure and is emitted perpendicularly upward. In this event, assuming that the laser light is emitted from the back surface side of the substrate, if it is larger than a band gap of the substrate, the laser light is absorbed by the substrate so that the light power is reduced.

It is therefore necessary to set the reflectivity of the top DBR mirror layer structure lower than that of the bottom DBR mirror layer structure to emit the laser light from the upper end surface of the mesa structure. It is also necessary to fabricate the electrode formed on the upper end surface of the mesa structure in a ring shape to provide a central hole of the ring as a laser light emitting surface (window) as described above.

However, the size of the ring-shaped electrode disposed on the upper end surface of the mesa structure is restricted as follows. Specifically, the outer diameter of the electrode cannot be made larger than the diameter of the upper end surface of the mesa structure, but, in spite of that, a laser light emitting window must be ensured, so that the inner diameter of the electrode needs to have a certain size or more. Consequently, even if an attempt is made to increase the width of the electrode to provide a larger contact area with the mesa structure, the above restriction limits the realization of an increased contact area. This results in an increased contact resistance of the electrode and the upper end surface of the mesa structure, causing heat generation in the laser device and a requirement for an increased operating voltage. Moreover, the increased operating voltage of the device gives rise to a problem of increased power consumption.

### OBJECT AND SUMMARY OF THE INVENTION

It is an object of the present invention to provide a vertical cavity surface emitting laser device which has an increased area of an upper end surface of a mesa structure to increase a contact area of the mesa structure with an electrode, thereby suppressing an increase in operating voltage to prevent the heat generation in the device.

It is another object of the present invention to provide a vertical cavity surface emitting laser array which is comprised of a plurality of the foregoing laser devices formed on a single semiconductor substrate.

To achieve the above objects, the present invention provides a vertical cavity surface emitting laser device comprising:

a bottom DBR mirror layer structure, an active layer, a current confinement layer and a top DBR mirror layer structure formed on a semiconductor substrate:

a portion including the top DBR mirror layer structure and an underlying region extending at least to a lower end surface of the current confinement layer being formed in a columnar mesa structure; and

the columnar mesa structure having an upper end surface of an area larger than a cross section at a lower portion of the columnar mesa structure.

In addition, the present invention provides a vertical cavity surface emitting laser array comprising a plurality of layered structures formed on a single semiconductor substrate, each layered structure including the bottom DBR mirror layer structure and the top DBR mirror layer structure in the vertical cavity surface emitting laser device set forth above.

### BRIEF DESCRIPTION OF THE DRAWINGS

FIG. 1 is a cross-sectional view illustrating the structure of a conventional vertical cavity surface emitting laser device;

FIG. 2 is a cross-sectional view illustrating the structure of a vertical cavity surface emitting laser device according to the present invention;

FIG. 3 is a cross-sectional view illustrating a laminate structure A;

FIG. 4 is a schematic diagram illustrating how the laminate structure A is etched to form a mesa structure;

FIG. 5 is a schematic diagram illustrating an oxidization process for the mesa structure;

FIG. 6 is a schematic diagram illustrating a site at which a ring-shaped electrode is disposed;

FIG. 7 is a schematic diagram illustrating the formation of a laser light emitting surface; and

FIG. 8 is a cross-sectional view illustrating the structure of another vertical cavity surface emitting laser device according to the present invention.

### DETAILED DESCRIPTION OF THE INVENTION

The present invention is based on a technical concept that the area of an upper end surface of a mesa structure is increased to allow a ring-shaped electrode to be formed thereon with a larger outer diameter and accordingly a larger ring width of the electrode, resulting in an increased contact area of the electrode with the mesa structure to reduce a contact resistance therebetween. In this event, when the diameter of the entire mesa structure is increased to provide a wider area for the upper end surface of the mesa structure, the diameter of a layer (precursor layer) to be converted into a current confinement layer also becomes necessarily larger in the mesa structure. Further, this requires a longer time for the aforementioned oxidization of the precursor layer in a high temperature steam atmosphere, needed to form the current confinement layer, resulting in a susceptibility to a lower productivity. Moreover, since a longer time required for the oxidization process causes difficulties in controlling the progress of the oxidization, resulting current restricting layers may vary in characteristics.

In view of these considerations, the present invention solves the problems mentioned above by substantially increasing only the area of an upper end surface of a mesa structure on which a ring-shaped electrode is formed, while avoiding an increased cross section of the mesa structure near a current confinement layer.

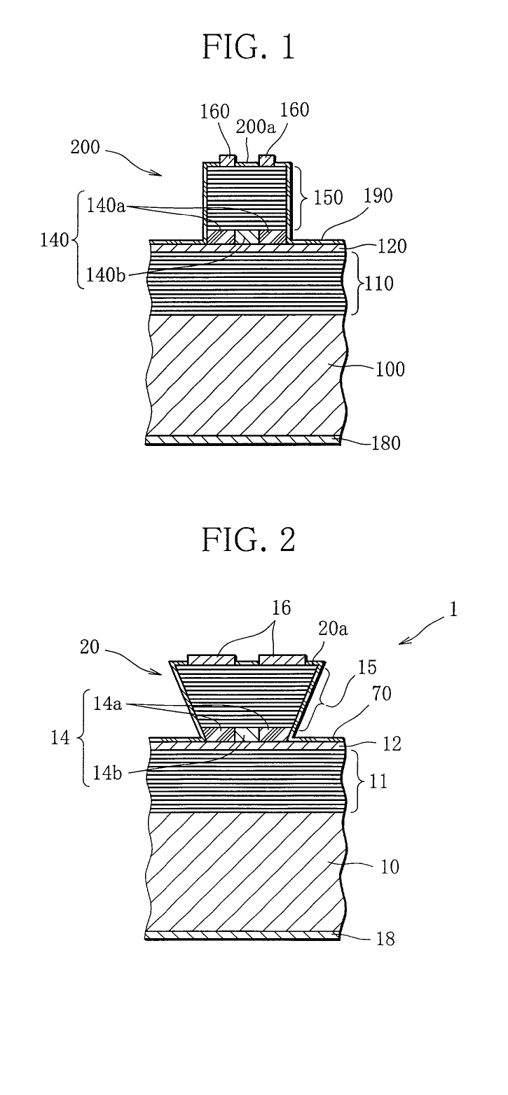

In the following, a vertical cavity surface emitting laser device according to the present invention will be described with reference to FIG. 2.

In FIG. 2, a vertical cavity surface emitting laser device 1 has a semiconductor substrate 10 (of approximately 150 μm in thickness) made of n-type GaAs, on which are formed a bottom DBR mirror layer structure (lower DBR mirror) 11 comprised of 25 pairs of n-type Al_{0.2}Ga_{0.8}As layers/n-type Al_{0.9}Ga_{0.1}As layers, and a top DBR mirror layer structure (upper DBR mirror) 15 comprised of 23 pairs of p-type Al_{0.2}Ga_{0.8}As layers/p-type Al_{0.9}Ga_{0.1}As layers. Then, between the DBR mirrors 11 and 15, a GaAs active layer 12 of a quantum well structure (including overlying and underlying clad layers) and a current confinement layer 14 are interposed in this order from the lower side, thus completing as a whole a layered structure comprised of semiconductor materials.

A portion including the upper DBR mirror 15, and an underlying region extending to a lower end surface of the current confinement layer 14 (interface between the current confinement layer 14 and the active layer 12) appears as a mesa structure 20 (with an upper end surface having a diameter of 50 μm, a base having a diameter of 30 μm, and a height of 3.1 μm) in the shape of an inverted circular truncated cone which is tapered downward. On the upper end surface 20a of the mesa structure 20, a ring-shaped p-type electrode 16 (having a width of 15 μm and an outer diameter of approximately 50 μm) is formed concentrically with the mesa structure 20. On a back surface of the semiconductor substrate 10, an n-type electrode 18 is disposed. The overall surface of the vertical cavity surface emitting laser device 1 is passivated with an SiNx film 70.

Semiconductor materials applicable to the laser device of the present invention are not limited to the foregoing GaAs-based compound semiconductor materials, but InP-based compound semiconductor materials, for example, may be used as well.

The bottom DBR mirror layer structure 11 and the top DBR mirror layer structure 15, which function as laser reflecting mirrors to constitute a resonator, can be formed by alternately laminating two types of semiconductor films (AlGaAs layers) having different refractive indexes from each other, as described above. In this case, the optical thickness of each semiconductor film may be chosen to be λ/4n (λ: wavelength of laser output light, n:refractive index). Also, a layer having an intermediate composition may be provided on interfaces of the respective films for reducing the resistance of the laser device.

Then, laser light can be emitted from the upper end surface 20a of the mesa structure 20 by setting the reflectivity of the top DBR mirror layer structure 15 lower than that of the bottom DBR mirror layer structure 11. Also, each of the reflecting mirror layer structures 11, 15 is preferably made of an n-type or a p-type semiconductor in accordance with the polarity of the laser. For example, with the laser device structure illustrated in FIG. 2, the bottom DBR mirror layer structure 11 may be chosen to be n-type, while the top DBR mirror layer structure 15 p-type. It should be noted that the composition ratio of Al in AlGaAs constituting the semiconductor films should be lower to prevent the respective mirror layer structures 11, 15 from oxidizing when the current confinement layer 14, later described, is formed. Further, instead of the foregoing semiconductor multi-layer film, each of the reflecting mirror layer structures may be formed of a dielectric multi-layer film or a metal thin film.

An active layer 12 produces light by re-combination of electrons and holes. Particularly, the active layer 12 of a quantum well structure is preferable because a threshold value can be set lower. In addition, clad layers having a larger band gap and a lower refractive index than the active layer 12 may be disposed overlying and underlying the active layer 12 as appropriate to sandwich the active layer 12 with the clad layers to confine electrons and light in the active layer 12. For the active layer 12 (and the overlying and underlying clad layers), a GaAs semiconductor may be used for emitting light at 850 nm, by way of example. Also, for forming the clad layers, a trace amount of Al, for example, may be doped into the clad layers to provide them with a larger band gap than that of the active layer 12.

The current confinement layer 14, which is in the shape of inverted circular truncated cone, has a concentric annular structure comprised of a core portion which serves as an electrically conductive layer 14b and an outer peripheral portion which serves as an insulating layer 14a. Since a current is intensively injected into the conductive layer 14b, a threshold current is reduced. Then, for example, after forming the mesa structure having an Al containing compound semiconductor layer as a precursor layer, oxidization is advanced from the lateral side to the core portion of the mesa structure to convert an outer peripheral portion into the insulating layer 14a mainly comprised of an Al oxide, while unoxidized Al containing compound semiconductor layer is left in the core portion and used as the conductive layer 14b. The Al containing compound semiconductor layer may be, for example, an AlAs layer, and an AlGaAs layer having a high Al composition. Specifically, in this embodiment, a p-type Al_{0.98}Ga_{0.02}As layer is used as the Al containing compound semiconductor layer (precursor layer).

It should be noted that when the mesa structure is in the shape of inverted circular truncated cone, the conductive layer 14b, formed in the core portion of the current confinement layer 14, is also in the shape of inverted circular truncated cone, however, an actual current confining effect occurs in the most tapered portion (lower end surface) of the conductive layer 14b, so that the conductive layer 14b formed in this shape will not cause any problem.

Here, while the current confinement layer 14 is formed between the active layer 12 and one or both of the reflecting mirror layer structures 11, 15, or within one reflecting mirror structure, the formation of the current confinement layer 14 in the p-type layer is preferred. Therefore, when a p-type substrate is used as the substrate 10, the current confinement layer 14 may be formed between the active layer 12 and the bottom DBR mirror layer structure 11, or within the bottom DBR mirror layer structure 11.

The p-type electrode 16 may be formed of, for example, an Au-Zn ally, Ti/Pt/Au, or Cr/Au. The n-type electrode 18 in turn may be formed, for example, of an Au-Ge alloy, an Au-Sn alloy or the like. Then, a contact layer made of a p-type compound semiconductor may be formed as appropriate on the surface on which the p-type electrode 16 is formed (the upper end surface 20a of the mesa structure in this embodiment) in the foregoing semiconductor layer structure. In this way, low resistance ohmic contacts can be realized between the electrodes and the semiconductor layer structure. Such a contact layer may be formed, for example, by doping a GaAs semiconductor with a p-type dopant such as Zn, Cd, Be, Mg, C or the like.

Each of the layers in the semiconductor layer structure may be formed, for example, by molecular beam epitaxy (MBE) or metal organic chemical vapor deposition (MOCVD).

The laser device 1 is characterized in that the area of the upper end surface 20a of the mesa structure 20 is larger than the cross section of the mesa structure 20 near the current confinement layer 14, as described above. The cross section of the mesa structure 20 near the current confinement layer 14, used herein, refers to the cross section of the mesa structure 20 in a region extending from an upper end surface to a lower end surface of the current confinement layer 14. If the mesa structure 20 in this portion lacks the consistency in the cross section in the vertical direction, the value of the portion having the smallest area is employed as the cross section. For example, if this portion is in the shape of circular truncated cone as mentioned above, the cross section of the mesa structure 20 on the bottom (lower end surface of the current confinement layer 14) is employed.

When the mesa structure is in the shape of inverted circular truncated cone, the p-type electrode 16 formed on the upper end surface 20a of the mesa structure 20 has a larger outer diameter, so that the width of the ring-shaped electrode can be increased if the size of the laser light emitting window is fixed. For this reason, a contact area of the electrode with the mesa structure can be increased, thus leading to a reduced contact resistance therebetween, and furthermore, a suppression of an increased operating voltage to prevent heat generation in the laser device. For example, in the foregoing embodiment, the p-type electrode 16 has the diameter of approximately 50 μm which is larger than the outer diameter of a p-type electrode (approximately 30 μm) in a conventional laser device. Also, the p-type electrode 16 has the width of 15 μm which is wider than that of the conventional electrode (5 μm). Therefore, the contact area of the electrode 16 with the upper end surface 20a of the mesa structure 20 is increased approximately four times as compared with the conventional laser device.

On the other hand, the cross section of the mesa structure 20 near the current confinement layer 14 is small as compared with the area of the upper end surface of the mesa structure 20, and may be similar to the value in the conventional laser device. In this event, since the diameter of the precursor to be converted into the current confinement layer 14 is also small as compared with the diameter of the upper end surface of the mesa structure 20, a long time is not required for the oxidization process which is performed for forming the current confinement layer 14, so that the productivity will not be degraded. In addition, since the oxidation process need not be performed for a long time, the advance of the oxidization can be controlled in a manner similar to the manufacturing of the conventional laser device, thereby preventing variations in the characteristics of resulting current confinement layers.

It should be noted that the shape of the mesa structure 20 is not limited to the aforementioned inverted circular truncated cone, and alternatively, the mesa structure 20 may be formed such that the upper end surface of the mesa structure is enlarged in the shape of flange, and an underlying region including the current confinement layer is formed in the shape of a cylinder having a diameter smaller than that of the upper end surface.

Then, the thus fabricated vertical cavity surface emitting laser device 1 can drive laser light in a 850 nm band at a low threshold value (2 mA) and with a low operating voltage (1.95 V at 20 mA).

Next, a method of fabricating the vertical cavity surface emitting laser device 1 will be described.

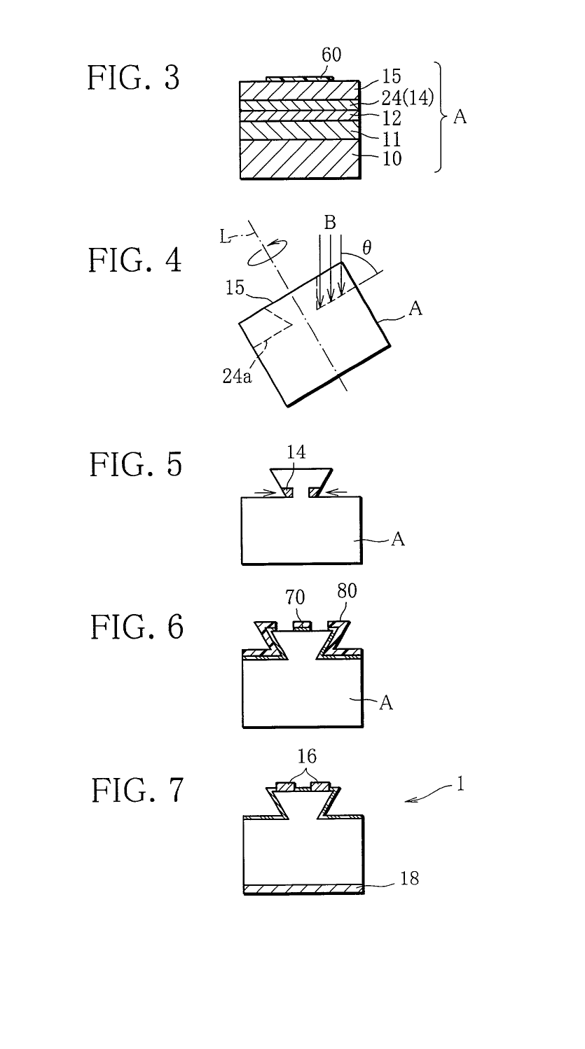

First, the respective layers 11, 12, 24, 15 mentioned above are laminated in this order on the semiconductor substrate 10 made of n-type GaAs, for example, by MBE (among these layers, the precursor layer 24 is a layer which is later converted into the current confinement layer 14). Then, a resist is coated on the top DBR mirror layer structure 15, which is the topmost surface of the resulting laminate structure A, and is patterned, for example, by photolithography, to form a resist pattern 60 which has the same shape as an intended shape of the upper end surface of the mesa structure (see FIG. 3).

Next, the mesa structure is formed by dry etching, for example, RIBE or the like which has a directivity. In this event, the laminate structure A is positioned in an etching apparatus at a predetermined angle θ to a direction in which a beam B is irradiated, such that the laminate structure A is irradiated with the beam B at an incident angle θ (see FIG. 4). Then, a portion extending from the top DBR mirror layer structure 15 down to the lower end surface 24a of the precursor layer 24 (converted into the current confinement layer) is selectively removed by etching. If an additional layer is formed between the precursor layer 24 and the underlying active layer 12, these layers may be etched together, including the additional layer. Alternatively, this additional layer may not be etched. In essence, what is required is to etch the portion including the precursor layer 24 to form the overall mesa structure so that the wet oxidization process, later described, can be performed from a lateral side of the mesa structure.

Then, the etching is continued while rotating the laminate structure A about a center axis L of the mesa structure to form a mesa structure of an inverted circular truncated cone shape which has a generatrix at an angle 0 with respect to the bottom. It should be noted that while the mesa structure is formed in the shape of inverted circular truncated cone in this example, the mesa structure is not limited to this particular shape, but may be formed, for example, in the shape of inverted quadrangular pyramid or inverted triangular pyramid.

Subsequently, the laminate structure A formed with the mesa structure undergoes the wet oxidization process to selectively oxidize only the precursor layer 24 from the lateral side of the mesa structure to convert the precursor layer 24 into the current confinement layer 14 (see FIG. 5). As the wet oxidization process, high temperature steam oxidization is preferred, as mentioned above, in which case the speed and/or degree of the oxidization can be varied by changing the dew point of steam, heat treatment temperature, processing time, and so on. The high temperature steam oxidization, if employed, may be performed, for example, at 400° C. for ten minutes.

Next, the overall surface of the laminate structure A is passivated with an SiNx layer 70. Then, a resist pattern 80 is formed, for example, by photolithography for a ring-shaped electrode, later described. Further, the SiNx layer 80 in a portion in which the ring-shaped electrode is formed is removed by dry etching, for example, RIE (reactive ion etching) or the like (see FIG. 6).

Then, a lift-off method is applied to form the p-type electrode 16 made of an Au-Zn alloy film on the upper end surface of the foregoing mesa structure. Subsequently, the resist pattern 80 is removed to expose a portion of the mesa structure inside the p-type electrode 16 and use this exposed portion as a laser light emitting surface. On the other hand, the back surface of the n-type semiconductor substrate 10 is lapped to reduce the thickness to approximately 150 μm, and subsequently a film of an Au-Ge alloy, for example, is formed on the lapped back surface as the n-type electrode 18 (see FIG. 7), thus completing the vertical cavity surface emitting laser device 1.

While the foregoing description has been made for the case where an n-type semiconductor substrate is used, the vertical cavity surface emitting laser device 1 can be fabricated substantially in the same manner when a p-type semiconductor substrate is used, so that detailed description thereon is omitted.

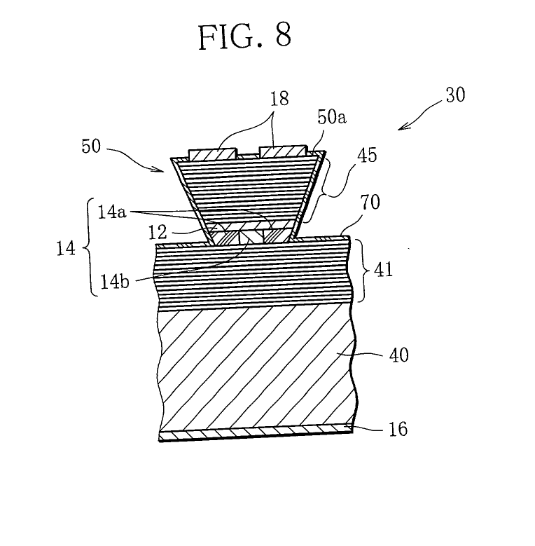

It should be noted however that with a p-type semiconductor, the upper and lower electrodes have the opposite polarities to those of the laser device using an n-type semiconductor substrate, so that the semiconductor structure must be fabricated in reverse. Specifically, as illustrated in FIG. 8, a current confinement layer 14 and an active layer 12 are interposed in order from the lower side between a bottom DBR mirror layer structure 41 and a top DBR mirror layer structure 45 formed on a p-type semiconductor substrate 40 to provide a semiconductor structure. Then, a p-type electrode 16 is formed on the back surface of the semiconductor substrate 40, while a ring-shaped n-type electrode 18 is formed on an upper end surface 50a of the mesa structure 50. When the p-type semiconductor substrate 40 is used, a bottom DBR mirror layer structure 41 formed on the substrate 40 is made of p-type semiconductor films similar to the reflecting mirror layer structure 15, while the top DBR mirror layer structure 45 is made of n-type semiconductor films similar to the reflecting mirror layer structure 11.

Likewise, in this embodiment, a portion extending from the surface of the top DBR mirror layer structure 45 positioned topmost to a region including the precursor layer is formed into the mesa structure 50 of an inverted circular truncated cone shape. This precursor layer can be converted into the current confinement layer 14 to fabricate a surface emitting laser device 30. In this case, since the ring-shaped n-type electrode formed on the upper end surface 50a of the mesa structure 50 can have a larger outer diameter, a contact area of the n-type electrode with the mesa structure is increased to reduce a contact resistance therebetween.

A vertical cavity surface emitting laser array according to the present invention has a plurality of the vertical cavity surface emitting laser devices 1 or 30 disposed on a common substrate (the same plane), i.e., the vertical cavity surface emitting laser devices are integrated on the same substrate.

As described above, the vertical cavity surface emitting laser device according to the present invention has the area of the upper end surface of the mesa structure larger than the cross section of the mesa structure near the current confinement layer, so that the ring-shaped electrode formed on the upper end surface of the mesa structure can have a larger outer diameter. As a result, the electrode, which is wider in width, provides for a larger contact area of the electrode with the mesa structure to reduce a contact resistance therebetween, thereby making it possible to output the laser light at a low operating voltage and to prevent heat generation in the laser device.

Also, the cross section of the mesa structure near the current confinement layer is smaller than the area of the upper end surface of the mesa structure, and is equivalent to that in the conventional laser device. In this case, the diameter of the precursor to be converted into the current confinement layer is also smaller than the diameter of the upper end surface of the mesa structure, so that a long time is not required for the oxidization process which is performed for forming the current confinement layer, with the result that the productivity will not be degraded. In addition, since the oxidation process need not be performed for a long time, the advance of the oxidization can be controlled in a manner similar to the manufacturing of the conventional laser device, thereby preventing variations in the characteristics of resulting current confinement layers. Consequently, the laser light can be stably output at a low threshold value.

What is claimed is:

1. A vertical cavity surface emitting laser device comprising:
a bottom DBR mirror layer structure, an active layer, a current confinement layer and a top DBR mirror layer structure formed on a semiconductor substrate;
a portion including said top DBR mirror layer structure and an underlying region extending at least to a lower end surface of said current confinement layer being formed in a columnar mesa structure; and
said columnar mesa structure having an upper end surface of an area larger than a cross section at a lower portion of said columnar mesa structure.

2. A vertical cavity surface emitting laser array comprising:
a plurality of layered structures formed on a single semiconductor substrate, each layered structure including the bottom DBR mirror layer structure and the top DBR mirror layer structure in the vertical cavity surface emitting laser device according to claim 1.
